(19) United States
(12) Patent Application Publication
(10) Pub. No.: US 2026/0153173 A1
(43) Pub. Date: Jun. 4, 2026

(54) ROTARY AXIS FLUID SUPPLY DEVICE

(71) Applicant: SEALINK CORP., Seoul (KR)

(72) Inventor: Hee Jang RHEE, Gunpo-si Gyeonggi-do (KR)

(73) Assignee: SEALINK CORP., Seoul (KR)

(21) Appl. No.: 19/092,130

(22) Filed: Mar. 27, 2025

(30) Foreign Application Priority Data
Nov. 29, 2024 (KR) 10-2024-0174282
Dec. 26, 2024 (KR) 10-2024-0197439

(51) Int. Cl. F16L 27/08; H01L 21/687

(52) U.S. Cl. CPC F16L 27/0845; H10P 72/7626

(57) ABSTRACT

A rotary axis fluid supply device is provided. The rotary axis fluid supply device according to an embodiment of the disclosure includes a rotating hollow outer housing, an inner housing accommodated in the outer housing, a hollow rotary shaft accommodated in the inner housing, fixed to the outer housing, and rotating with the outer housing, a fluid supply port housing accommodating one end of the rotary shaft and allowing the rotary shaft to rotate inside, a first sealing portion sealing between the inner housing and the rotary shaft, and a second sealing portion sealing between the fluid supply port housing and the rotary shaft, wherein fluid is supplied from the fluid supply port housing to a fluid supply path inside the hollow rotary shaft.

### CROSS-REFERENCE TO RELATED APPLICATIONS

This application claims priority to Korean Patent Application No. 10-2024-0174282 filed on Nov. 29, 2024, and Korean Patent Application No. 10-2024-0197439 filed on Dec. 26, 2024, the entire contents of which are herein incorporated by reference.

### BACKGROUND

### 1. Field

The disclosure relates to a rotary axis fluid supply device capable of supplying fluid through a hollow rotary shaft that is accommodated in an inner housing, is fixed to an outer housing, and rotates with the outer housing.

### 2. Description of the Related Art

A semiconductor substrate processing apparatus includes a chamber in which a substrate processing process is performed, and a susceptor in which a substrate is seated inside the chamber. In addition, a shaft and a driving unit are provided for a linear motion and/or a rotational motion of the susceptor. Here, the driving unit is provided outside the chamber, and the shaft is provided penetrating the chamber.

Here, a seal for sealing a part coupled to the chamber is provided in the shaft. The shaft performs the linear motion and/or the rotational motion, which causes friction between the shaft and the seal.

In the related art, a mechanical seal unit was used as such a seal device. The mechanical seal unit uses lubricant, which causes oil to penetrate into the chamber and involves a risk of contamination and explosion. In particular, when powder is formed inside a reaction chamber, the powder may penetrate between mechanical seals, which may cause rapid shortening of the life. The mechanical seal unit uses a material that is in surface contact, such as carbon, silicon carbide, hard metal, etc., and there is a problem in that when small solid particles penetrate between surface contacts, damage to the contact surface may easily occur.

When the seal is damaged by repeated friction, there may be a risk such as gas leakage. In addition, because there may be an emergency leak of gas due to sudden temperature and pressure changes inside the chamber, it is necessary to develop a device capable of sealing between the shaft and the chamber even in an emergency situation.

### SUMMARY

The disclosure is directed to providing a rotary axis fluid supply device which may solve a problem of particle infiltration by using a linear contact method.

The disclosure also provides a rotary axis fluid supply device capable of preventing fluid leakage under pressure and vacuum conditions by improving a sealing force between a housing and a shaft while replacing a mechanical seal.

The disclosure also provides a rotary axis fluid supply device capable of supplying fluid through a hollow rotary shaft that is accommodated in an inner housing, is fixed to an outer housing, and rotates with the outer housing.

The solutions of the disclosure are not limited to the above-mentioned contents, and other technical problems not mentioned will be clearly understood by one of ordinary skill in the art from the following description.

### Solution to Problem

According to an embodiment of the disclosure, a rotary axis fluid supply device includes a rotating hollow outer housing, an inner housing accommodated in the outer housing, a hollow rotary shaft accommodated in the inner housing, fixed to the outer housing, and rotating with the outer housing, a fluid supply port housing accommodating one end of the rotary shaft and allowing the rotary shaft to rotate inside, a first sealing portion sealing between the inner housing and the rotary shaft, and a second sealing portion sealing between the fluid supply port housing and the rotary shaft, wherein fluid is supplied from the fluid supply port housing to a fluid supply path inside the hollow rotary shaft.

Each of the first sealing portion and the second sealing portion may include a plurality of lip seals with curved lips formed on an inner circumferential surface of an annular sealing.

Each of the plurality of lip seals may have a plurality of curved lip portions provided on one body portion.

At least two of the plurality of curved lip portions may be curved in different directions.

A power transmission unit to which a gear or a pulley is connected to transmit rotational power may be provided on an outer periphery of the outer housing.

One or more of the first sealing portion and the second sealing portion may include a purge flow path for discharging foreign substances around the seals to the outside.

The rotary axis fluid supply device may further include a first bearing portion supporting rotation of the hollow rotary shaft between the hollow rotary shaft and the inner housing, and a second bearing supporting rotation of the rotary shaft between the fluid supply port housing and the rotary shaft.

One end of the hollow rotary shaft may be connected to a semiconductor loading unit of a semiconductor substrate processing apparatus, and the fluid supplied to the fluid supply path of the rotary shaft may be supplied to a semiconductor substrate through the loading unit.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram illustrating a rotary axis fluid supply device and a semiconductor substrate processing apparatus according to an embodiment of the disclosure;

FIG. 2 is a perspective view of the rotary axis fluid supply device according to an embodiment of the disclosure;

FIG. 3 is a front view of the rotary axis fluid supply device of FIG. 2;

FIG. 4 is a cross-sectional view of the rotary axis fluid supply device of FIG. 3; and

FIGS. 5A, 5B, and 5C illustrate various lip seals that may be used in the rotary axis fluid supply device according to an embodiment of the disclosure.

### DETAILED DESCRIPTION

Embodiments will be described more fully hereinafter with reference to the accompanying drawings so that they may be easily implemented by one of ordinary skill in the art to which the disclosure belongs. However, the disclosure may be implemented in different forms and should not be construed as being limited to the embodiments set forth herein. In addition, in order to clearly explain an embodiment of the disclosure in the drawings, parts that are not related to the explanation are omitted.

The terms used herein are only used to describe particular embodiments, and are not intended to limit the disclosure. Singular expressions used herein are intended to include plural expressions as well unless the context clearly indicates otherwise.

The terms such as “comprise,” “include,” or “have” used herein may be understood as being intended to specify the presence of stated features, numbers, steps, operations, elements, components, or combinations thereof, but do not preclude the presence or addition of one or more other features, numbers, steps, operations, elements, components, or combinations thereof.

In addition, the following embodiments are provided to more clearly explain to one of average knowledge in the art, and the shape and size of elements in the drawing may be exaggerated for clearer explanation.

Hereinafter, preferred embodiments according to the disclosure will be described with reference to the accompanying drawings.

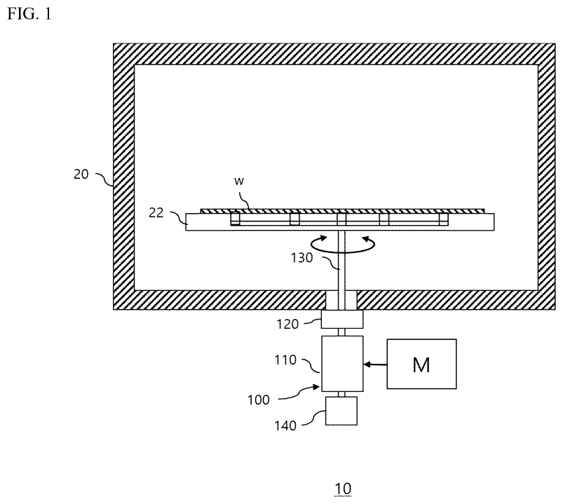

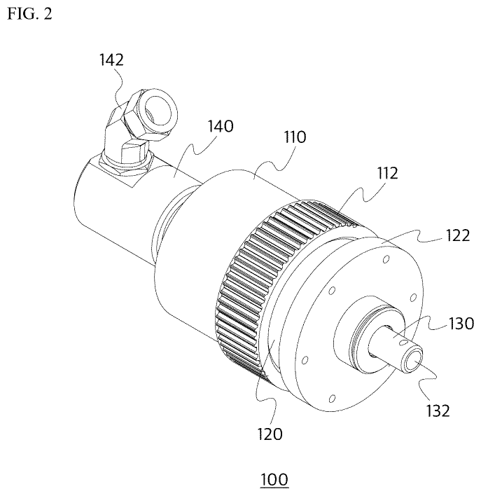

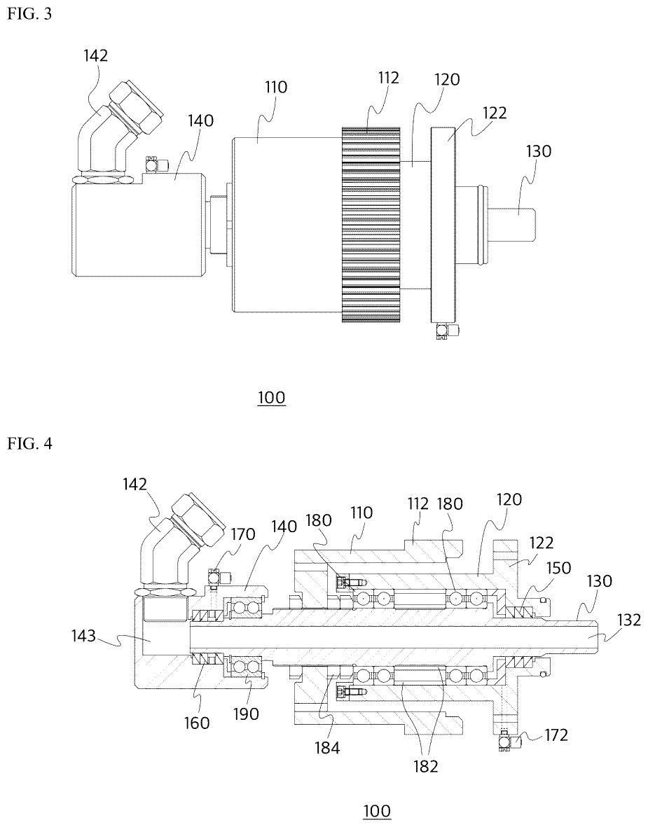

FIG. 1 is a diagram illustrating a rotary axis fluid supply device and a semiconductor substrate processing apparatus according to an embodiment of the disclosure. FIG. 2 is a perspective view of the rotary axis fluid supply device according to an embodiment of the disclosure. FIG. 3 is a front view of the rotary axis fluid supply device of FIG. 2. FIG. 4 is a cross-sectional view of the rotary axis fluid supply device of FIG. 3.

First, referring to FIG. 1, a semiconductor substrate processing apparatus 10 according to an embodiment of the disclosure may include a rotary axis fluid supply device 100 and a chamber 20. Chemical vapor deposition (CVD) equipment, furnace equipment, sputtering equipment, etching equipment, etc. may be examples of the semiconductor substrate processing apparatus 10. The sputtering equipment is shown in FIG. 1. The semiconductor substrate processing apparatus 10 may include a loading unit 22 (susceptor) capable of loading semiconductor wafers inside the chamber 20 and the rotary axis fluid supply device 100 capable of supplying working fluid while rotating the loading unit 22. The rotary axis fluid supply device 100 may rotate the loading unit 22 at an appropriate speed and simultaneously prevent process gas in the chamber 20 from flowing to outside the chamber 20 or foreign substances outside the chamber 20 from flowing into the chamber 20. In addition, the rotary axis fluid supply device 100 may receive working fluid from the outside and supply the working fluid through a fluid supply hole provided in the loading unit 22 through a hollow shaft 130.

Referring to FIGS. 2 to 4, the rotary axis fluid supply device 100 according to an embodiment of the disclosure is provided to rotate the semiconductor loading unit 22 and simultaneously supply the working fluid into the chamber 20. The rotary axis fluid supply device 100 may include an outer housing 110, an inner housing 120, the rotary shaft 130, a fluid supply port housing 140, a first sealing portion 150, and a second sealing portion 160.

The outer housing 110, which generally has a hollow shape with one end opened and the other end including a through hole into which the rotary shaft 130 may be inserted, may accommodate the inner housing 120 and the rotary shaft 130 therein. The outer housing 110 may be rotated by receiving rotational power from a separate power transmission device. In an embodiment, a power transmission unit 112 to which a gear or a pulley is connected to transmit the rotational power may be provided on an outer periphery of the outer housing 110. In the present embodiment, the power transmission unit 112 may have a shape with a protrusion formed such that the pulley may be coupled thereto, but is not limited thereto, and the power transmission unit 112 may have a gear unit formed to enable power transmission through the power transmission device and a gear.

The inner housing 120 may be accommodated in the outer housing 110 and rotate relative to the outer housing 110. More specifically, the inner housing 120 may not be rotated, and only the outer housing 110 may be rotated. The inner housing 120 may accommodate the rotary shaft 130 therein, and a flange portion 122 that may be fixedly mounted on the chamber 20 of the semiconductor substrate processing apparatus 10 may be provided on one end of the inner housing 120. That is, the inner housing 120 is fixed to the chamber 20 and does not rotate, but the outer housing 110 may rotate by receiving the rotational power from the power transmission device.

The rotary shaft 130 may be accommodated in the inner housing 120 and coupled to the outer housing 110 to rotate with the outer housing 110. Although a coupling method of the rotary shaft 130 and the outer housing 110 is not shown, the rotary shaft 130 and the outer housing 110 may be coupled to prevent mutual rotation by using various methods such as a coupling method by a structure in which rotation is prevented by separate bolt fastening, welding, or a cross-sectional shape. One end of the rotary shaft 130 may be connected to the semiconductor loading unit 22 of the semiconductor substrate processing apparatus 10 to rotate the semiconductor loading unit 22. That is, the rotary shaft 130 may transmit rotational force to the semiconductor loading unit 22. In addition, the rotary shaft 130 in a hollow shape may supply the working fluid to the semiconductor loading unit 22 through a fluid supply path 132 inside.

The fluid supply port housing 140 may be installed so that the rotary shaft 130 rotates inside while accommodating one end of the rotary shaft 130 in the opposite direction to the chamber 20. The fluid supply port housing 140 may also have a structure that does not rotate, and the working fluid supplied from the outside through the fluid supply port 142 may pass through a fluid supply chamber 143 and then be supplied to the fluid supply path 132 of the rotary shaft 130 communicating with the fluid supply chamber 143.

The first sealing portion 150 is provided to seal between the inner housing 120 and the rotary shaft 130. The first sealing portion 150 may include a plurality of seals disposed between the inner housing 120 and the rotary shaft 130 to seal a gap between the inner housing 120 and the rotary shaft 130. In the present embodiment, the plurality of seals 150 may include three seals, and each may be a lip seal having a curved lip formed on an inner circumferential surface of an annular sealing. In addition, each of the lip seals 150 may have one or more curved lip portions provided on one body portion. Thanks to the plurality of lip seals of the first sealing portion 150, gas or foreign substances in the chamber 20 may be prevented from being discharged to the outside through the rotary axis fluid supply device 100. Likewise, thanks to the plurality of lip seals of the first sealing portion 150, external particles or foreign substances may be prevented from entering the chamber 20.

The second sealing portion 160 is provided to seal between the fluid supply port housing 140 and the rotary shaft 130. The second sealing portion 160 may include a plurality of seals disposed between the fluid supply port housing 140 and the rotary shaft 130 to seal a gap between the fluid supply port housing 140 and the rotary shaft 130. In the present embodiment, the plurality of seals 160 may include three seals, and each may be a lip seal having a curved lip formed on an inner circumferential surface of an annular sealing. In addition, each of the lip seals 160 may have one or more curved lip portions provided on one body portion. Thanks to the plurality of lip seals of the second sealing portion 160, the fluid in the fluid supply chamber 143 of the fluid supply port housing 140 may be prevented from being discharged between the rotary shaft 130 and the fluid supply port housing 140, and may flow only through the fluid supply path 132 of the rotary shaft 130.

On the other hand, the rotary axis fluid supply device 100 according to an embodiment of the disclosure may include purge flow paths 172 and 170 for discharging foreign substances around seals to the outside, in at least one of the first sealing portion 150 or the second sealing portion 160. The first purge flow path 172 may include the purge flow path 172 provided in the inner housing 120 to prevent foreign substances from the chamber 20 of the semiconductor substrate processing apparatus 10 from flowing to the outside of the inner housing 120 of the rotary axis fluid supply device 100. More specifically, when a pneumatic device is connected to the first purge flow path 172 to form negative pressure, the first purge flow path 172 may suck and remove particles (foreign substances) generated from bearings 180 disposed between the inner housing 120 and the rotary shaft 130 or particles from the lip seal 150. In addition, because the first purge flow path 172 is in fluid communication with the gap between the rotary shaft 130 and the inner housing 120, the purge gas supplied through the first purge flow path 172 may flow toward the first sealing portion 150 and the chamber 20 through the gap, preventing the process gas from the chamber 20 from flowing to the gap. In addition, foreign substances formed in the gap may be sucked and discharged to the outside by forming negative pressure through an external pneumatic device in the first purge flow path 172.

The second purge flow path 170 may prevent particles (foreign substances) generated from bearings 190 disposed between the fluid supply port housing 140 and the rotary shaft 130 or particles from the lip seal 160 from accumulating. More specifically, when a pneumatic device is connected to the second purge flow path 170 to form negative pressure, the second purge flow path 170 may suck and remove particles (foreign substances) generated from the bearings 190 disposed between the fluid supply port housing 140 and the rotary shaft 130 or particles from the lip seal 160.

Meanwhile, the rotary axis fluid supply device 100 according to an embodiment of the disclosure may include the first bearing portions 180 and the second bearing portions 190. The first bearing portions 180 are provided between the hollow rotary shaft 130 and the inner housing 120 to support rotation of the rotary shaft 130 within the inner housing 120, and the second bearing portions 190 are provided between the fluid supply port housing 140 and the rotary shaft 130 to support rotation of the rotary shaft 130 within the fluid supply port housing 140. In addition, the first bearing portions 180 may be provided in a set of two each at an upper end and a lower end of the inner housing 120, and an annular spacer 182 may be provided between the first bearing portions 180. The annular spacer 182 may include two concentric annular spacers, one mounted on an outer circumferential surface of the rotary shaft 130, and the other mounted on an inner circumferential surface of the inner housing 120. In addition, locking nuts 184 for fixing positions of the first bearing portions 180 at the lower end may be provided. In addition, the second bearing portions 190 are provided at one end of the fluid supply port housing 140 outside the second sealing portion 160, thereby preventing the fluid in the fluid supply chamber 143 of the fluid supply port housing 140 from contacting the second bearing portions 190 and causing damage to the second bearing portions 190.

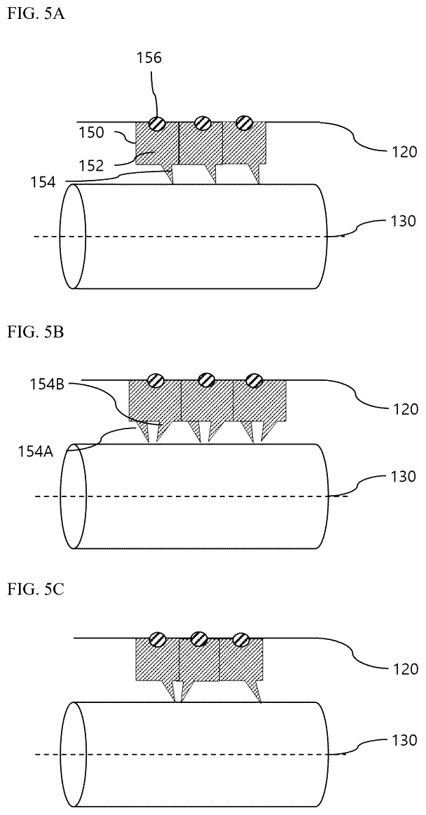

FIGS. 5A, 5B, and 5C illustrate various lip seals that may be used in the rotary axis fluid supply device according to an embodiment of the disclosure.

Referring to FIGS. 5A, 5B, and 5C, an example of the first lip seal portion 150 is shown, but the example is applicable to the second lip seal portion 160 in the same manner, and thus only the first lip seal portion 150 will be described below. Each of the lip seals 150 used in the rotary axis fluid supply device 100 according to an embodiment of the disclosure may have a shape in which a plurality of curved lip portions 154 are provided on one body portion 152.

As shown in FIG. 5A, when the three lip seals 150 are used, the lip portions 154 are curved in the same direction, as shown in FIG. 5B, lip portions 154A and 154B among the plurality of lip seals 150 may be curved in different directions, and as shown in FIG. 5C, each of the lip seals 150 includes the plurality of lip portions 154, and at least two of the plurality of curved lip portions 154 may be curved in different directions. In the case of FIG. 5A, when a vacuum is formed in the upper direction, all the lip portions 154 have shapes curved to the right to prevent foreign substances from the rotary axis fluid supply device 100 of each of the lip seals 150 from flowing to the chamber 20, and in the case of FIG. 5B, even though a vacuum is formed in either the upper direction or the lower direction, the lip portion 154A or the lip portion 154B may respond or even though one lip portion 154A is consumed or damaged, the other lip portion 154B may respond.

In an embodiment, an annular anti-rotation member 156 may be provided on an outer circumferential surface of each of the lip seals 150 toward the inner housing 120 to prevent relative rotation of each of the lip seals 150 with the shaft 130 within the inner housing 120. The anti-rotation member 156 serves to further pressurize the lip seal 150 toward the inner housing 120. In addition, the friction between the anti-rotation member 156 and the lip seal 150 is great compared to when there is no anti-rotation member 156, that is, when the lip seal 150 directly contacts an inner circumferential surface of the inner housing 120. Accordingly, the anti-rotation member 156 may suppress the lip seal 150 from relatively rotating with the shaft 130 within the inner housing 120.

In addition, when the rotary axis fluid supply device 100 is disassembled and assembled for reasons such as damage and inspection, even though the surface roughness of the inner housing 120 is relatively rough, the anti-rotation member 156 rubs against the inner circumferential surface of the inner housing 120 during a disassembly and assembly process, and thus the sealing portion 150 may minimize damage caused by low surface roughness of the inner housing 120. In addition, even though the anti-rotation member 156 is damaged to some extent, there is an advantage that the anti-rotation member 156 is reusable, and thus the rotary axis fluid supply device 100 may be more easily disassembled and assembled.

The rotary axis fluid supply device according to the above-described embodiment may solve a problem of particle infiltration by using a linear contact method. The rotary axis fluid supply device may also prevent fluid leakage under pressure and vacuum conditions by improving a sealing force between a housing and a shaft while replacing a mechanical seal, and may supply fluid through a hollow rotary shaft that is accommodated in an inner housing, is fixed to an outer housing, and rotates with the outer housing.

In the above, the disclosure has been described with specific details such as specific components, the limited embodiments and the drawings, but these are only provided to facilitate a more general understanding of the disclosure, the disclosure is not limited to the above embodiments, and those skilled in the art may achieve various modifications and changes based on the description.

Therefore, the spirit of the disclosure should not be limited to the above-described embodiments, and the claims described below as well as all modifications equally to or equivalent to the claims shall fall within the scope of the spirit of the disclosure.

What is claimed is:

1. A rotary axis fluid supply device comprising:
a rotating hollow outer housing;
an inner housing accommodated in the outer housing;
a hollow rotary shaft accommodated in the inner housing, fixed to the outer housing, and rotating with the outer housing;
a fluid supply port housing accommodating one end of the rotary shaft and allowing the rotary shaft to rotate inside;
a first sealing portion sealing between the inner housing and the rotary shaft; and
a second sealing portion sealing between the fluid supply port housing and the rotary shaft,
wherein fluid is supplied from the fluid supply port housing to a fluid supply path inside the hollow rotary shaft.

2. The rotary axis fluid supply device of claim 1, wherein each of the first sealing portion and the second sealing portion includes a plurality of lip seals with curved lips formed on an inner circumferential surface of an annular sealing.

3. The rotary axis fluid supply device of claim 2, wherein each of the plurality of lip seals has a plurality of curved lip portions provided on one body portion.

4. The rotary axis fluid supply device of claim 3, wherein at least two of the plurality of curved lip portions are curved in different directions.

5. The rotary axis fluid supply device of claim 1, wherein a power transmission unit to which a gear or a pulley is connected to transmit rotational power is provided on an outer periphery of the outer housing.

6. The rotary axis fluid supply device of claim 1, wherein one or more of the first sealing portion and the second sealing portion include a purge flow path for discharging foreign substances around the seals to an outside.

7. The rotary axis fluid supply device of claim 1, further comprising:
a first bearing portion supporting rotation of the hollow rotary shaft between the hollow rotary shaft and the inner housing; and
a second bearing supporting rotation of the rotary shaft between the fluid supply port housing and the rotary shaft.

8. The rotary axis fluid supply device of claim 1, wherein one end of the hollow rotary shaft is connected to a semiconductor loading unit of a semiconductor substrate processing apparatus, and
the fluid supplied to the fluid supply path of the rotary shaft is supplied to a semiconductor substrate through the loading unit.
